(19) United States
(12) Patent Application Publication
(10) Pub. No.: US 2005/0079643 A1
(43) Pub. Date: Apr. 14, 2005

(54) Fabrication method for light-emitting chips

(76) Inventor: Wen-Chih Ho, Taoyuan (TW)

Correspondence Address: RABIN & CHAMPAGNE, P.C., Suite 500, 1101 14 Street, N.W., Washington, DC, 20005, US

(21) Appl. No.: 10/682,424

(22) Filed: Oct. 10, 2003

(51) Int. Cl. H01L 21/44; H01L 21/00; H01L 21/48; H01L 21/50

(52) U.S. Cl. 438/26; 438/33

(57) ABSTRACT

A method fabricates light-emitting chips having a heat-dissipating structure to enhance its work efficiency and applications. By means of an appropriate bonding technique, the method mainly attaches an insulating, heat-dissipating substrate that has metal electrodes, to a chip that has metal blocks. The module of combined chip and the heat-dissipating substrate is cut into light-emitting chips with a heat-dissipating structure to serve as the light source of light-emitting diodes.

### BACKGROUND OF THE INVENTION

1. Field of Invention

The invention relates to a fabrication method for light-emitting chips and, in particular, to a method that can simultaneously produce several light-emitting chips with a heat-dissipating structure. This method can be applied for mass production of light-emitting chips. The heat-dissipating structure of the chips can effectively enhance their work efficiency and enlarge their application ranges.

2. Related Art

The invention of the light-emitting diode (LED) is as early as 1970s. It has had great influences on human life styles since then. People have also tried very hard to find more efficient and practical light sources for decades. However, no major breakthroughs have been found due to many technical problems. Such problems include the brightness enhancement and product lifetime. In recent years, some progresses have been made toward these directions, providing wider applications of the LED. In comparison with traditional light sources, the LED has many advantages, including a smaller volume, better light-emitting efficiency, longer lifetime, a faster operation and reaction speed, higher reliability, more robust against damages, and being able to be integrated into a small-size, coiling or arrayed element. Moreover, it does not cause thermal radiation and poisonous material (such as mercury) pollutions.

Currently, the fabrication technique of the LED has been quite mature and its brightness has been increased to a satisfactory level. Its applications cover vehicle panels, backlit source for liquid crystal display (LCD) panels, indoor illuminations, and the light sources in scanners and fax machines. Future goals are to make LED's with low power consumption while high brightness. The micro LED is another important direction. It mainly uses miniaturized LED's in the light sources of electronic devices, such as mobile phones, laptop computers or the backlit panels of PDA screens. The surface-bonding LED is very suitable for such electronic products.

With reference to FIG. 1, the conventional light-emitting chip 10 has a structure consisting of a base 101, a light-emitting layer 102, and electrodes 103. As shown in FIG. 2, their most commonly seen application is to fix the whole light-emitting chip 10 inside the basin 2011 of a frame 201. Through metal wires 203, 204, the light-emitting chip 10 is connected to the frames 201, 202, forming a conducting circuit. Finally, the module is packaged into an LED 20 using epoxy.

Considering the light-emitting efficiency, the power that the light-emitting chip in the LED can sustain plays an important role. The application of a high-power light-emitting chip can increase the brightness of a single LED and thus enlarge the application range of the LED. Therefore, how to increase the light-emitting efficiency of the chip is a big subject under study. The first problem that one has to solve is how to remove or reduce the working temperature once a current flows through the light-emitting chip. From data disclosed in the prior art we see that the heat dissipation structures of most LED's are done during the packaging process. Normally, a heat sink is connected to the chip during packaging. Examples include the liquid-cooled and the air-cooled LED's. Such heat-dissipating designs use exterior utilities to help carrying away heat from a working chip using liquid or gas. Thus, the LED thus made can have a higher power without experiencing any light attenuation effect. Although the exterior heat sink design can achieve the goal of heat dissipation, it also complicates the manufacturing process of packaging. Moreover, whether the exterior heat sink design can be correctly integrated during packaging is another issue to be worried about in quality control.

### SUMMARY OF THE INVENTION

In view of the foregoing, an objective of the invention is to provide a fabrication method for light-emitting chips so that the light-emitting chips thus made have a good heat dissipation character to enhance its high power applications.

Another objective of the invention is to provide a fabrication method for light-emitting chips that can provide a whole-area light source. Therefore, the chip can be used as the light source of an LED to enhance its efficiency.

The disclosed method can simultaneously produce several light-emitting chips with heat-dissipating substrates so that they are equipped with a heat-dissipating structure once finished. The method mainly combines an insulating, heat-dissipating substrate that is attached with a metal electrode and a chip that is attached with a metal block using an appropriate bonding technique. The module of combined chip and the heat-dissipating substrate is cut into light-emitting chips with a heat-dissipating structure as the light source of light-emitting diodes.

### BRIEF DESCRIPTION OF THE DRAWINGS

The invention will become more fully understood from the detailed description given hereinbelow illustration only, and thus are not limitative of the present invention, and wherein:

FIG. 1 is a plane schematic view of a conventional light-emitting chip;

FIG. 2 is a schematic view of a conventional light-emitting diode;

FIG. 3 is a schematic view of the material structure according to the invention;

FIG. 4 is another schematic view of the material structure according to the invention;

FIG. 5 shows one step of the disclosed implementation procedure;

FIG. 6 shows another step of the disclosed implementation procedure;

FIG. 7 shows another step of the disclosed implementation procedure;

FIG. 8 shows another step of the disclosed implementation procedure;

FIG. 9 shows another step of the disclosed implementation procedure;

FIG. 10 shows the light-emitting chip produced by the invention;

FIG. 11 is a top view of the light-emitting chip produced by the invention;

FIG. 12 shows a first embodiment of the invention;

FIG. 13 shows a step of the first embodiment;

FIG. 14 shows a second embodiment of the invention; and

FIG. 15 shows a step of the second embodiment.

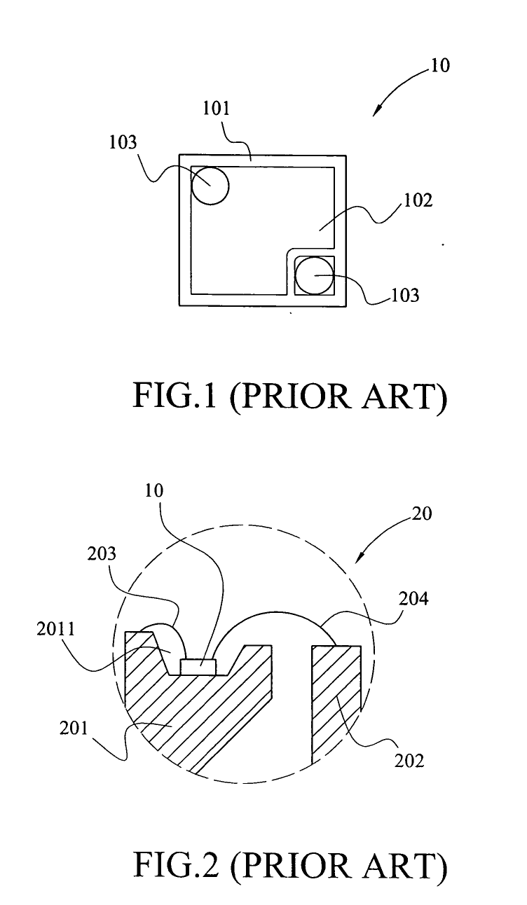

### DETAILED DESCRIPTION OF THE INVENTION

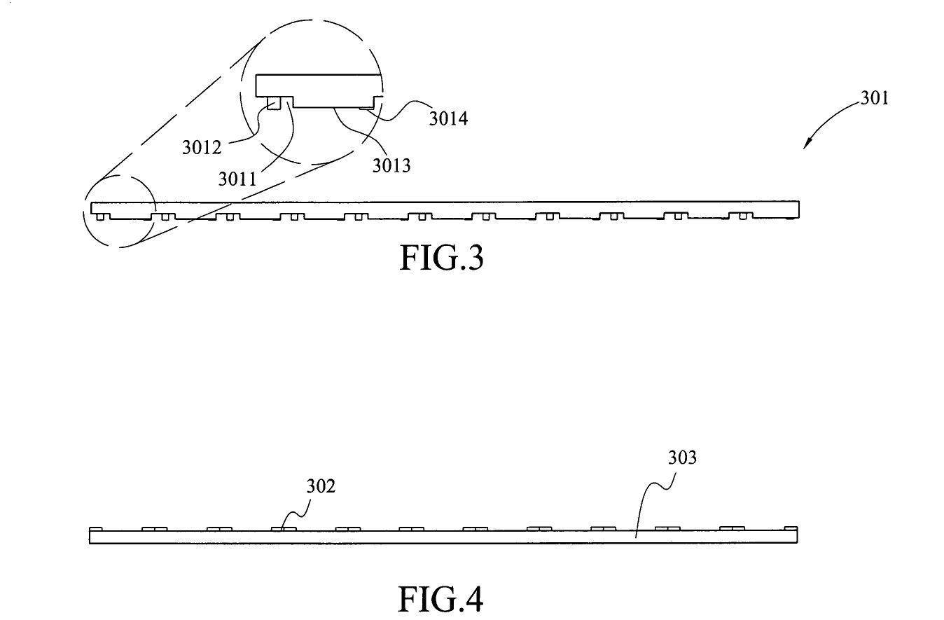

Please refer to FIG. 3, which shows an epitaxial chip 301 produced using the disclosed fabrication method. Its bottom has several grooves 3011 formed by laser machining or photolithography processes. Metal blocks 3012 are attached at appropriate locations inside the grooves 3011. The attachment can be achieved by electroplating, printing, and sputtering. The metal blocks 3012 can be made of gold, silver, tin and other electric and thermal conductive metals. Bottom attaching parts 3013, whose surfaces are attached with metal blocks 3014, are formed in equal distance among the grooves 3011. The attachment is achieved by electroplating, printing, and sputtering. Likewise, the metal blocks 3014 can be made of gold, silver, tin and other electric and thermal conductive metals.

FIG. 4 shows a heat-dissipating substrate 303 used in the invention. Its material can be ceramics, aluminum oxides or aluminum nitrides. These materials have good thermal conduction properties and are insulating. Before making the light-emitting chips, the heat-dissipating substrate 303 is first attached with a metal electrode 302. The attachment can be achieved by sputtering, evaporation, electroplating, and printing. From FIGS. 3 and 4, one can easily see that the metal electrode 302 on the heat-dissipating substrate 303 has a location exactly corresponding to the metal blocks 3012, 3014 on the bottom of the epitaxial chip 301.

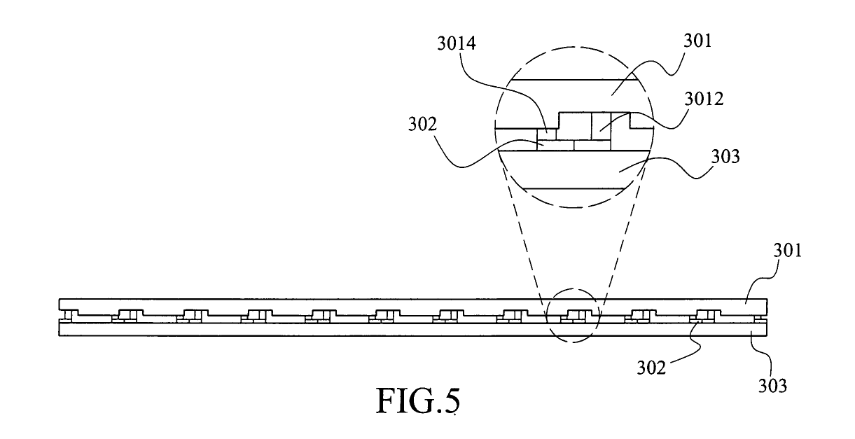

Please refer to FIG. 5. During the combination, each of the metal blocks 3012, 3014 on the bottom surface of the epitaxial chip 301 is first aligned with each of the metal electrodes 302 on the surface of the heat dissipating substrate 303. The bonding between the metal blocks 3012, 3014 and the metal electrode 302 can be achieved by electro-soldering, welding, or supersonic bonding. The drawing shows a finished product.

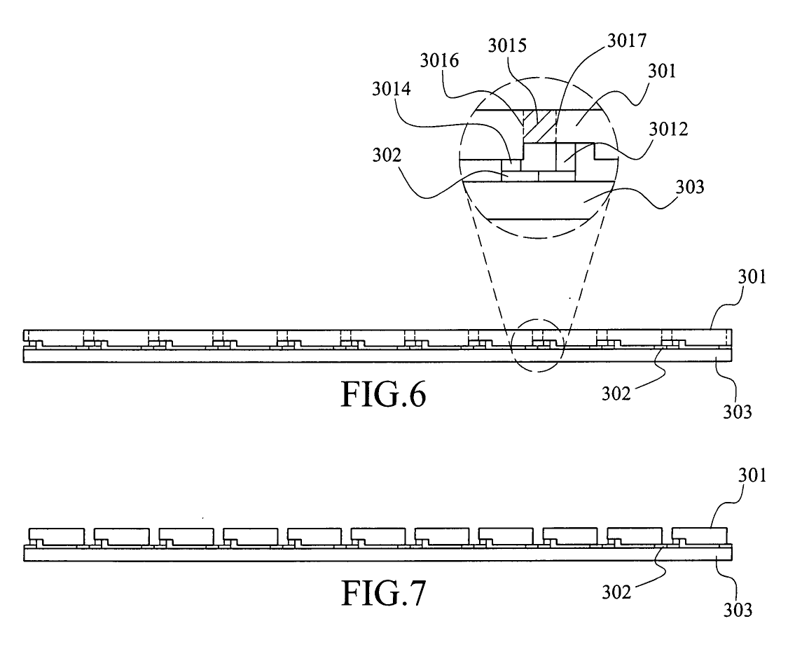

With reference to FIG. 6, after the bonding is completed a residual material 3015 is formed between the grooves 3011 and the metal blocks 3012, 3014 on the bottom of the epitaxial chip 301 and the metal electrodes 302 on the heat-dissipating substrate 303. The locations where both sides of the residual material 3015 are in line with the grooves 3011 are the cutting lines 3016, 3017.

When one cuts along the cutting lines 3016, 3017, the residual material falls off, forming the object shown in FIG. 7. Therefore, it is possible to form several individual chips separated by an equal distance. At this moment, each of the independent chips is still attached on the heat-dissipating substrate 302 due to the bonding of the metal electrodes 302.

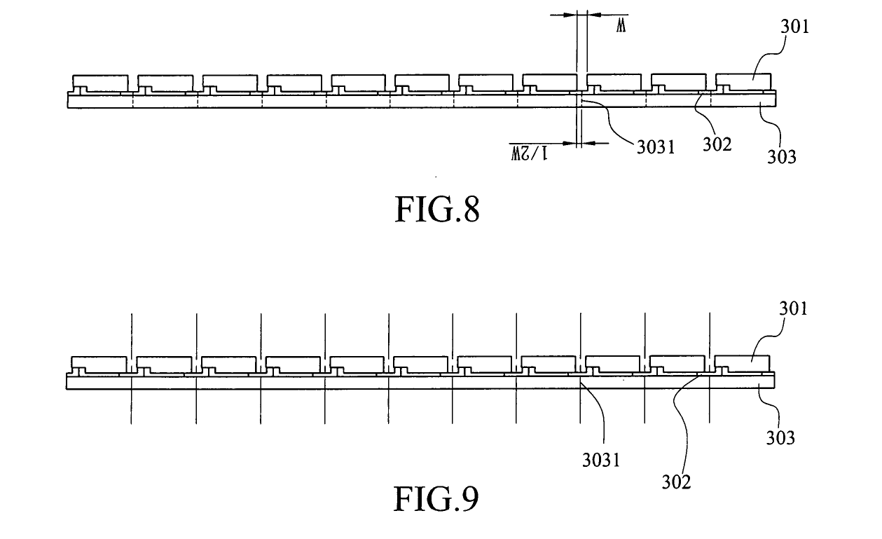

FIG. 8 shows the heat-dissipating substrate 304 before it is cut. Since the residual material among the chips above the heat-dissipating substrate 303 has been removed, a gap with a width W is formed between adjacent chips. We then use the central position in the gap W/2 for making cuts. It is the location of the cutting line 3031 on the heat-dissipating substrate 303.

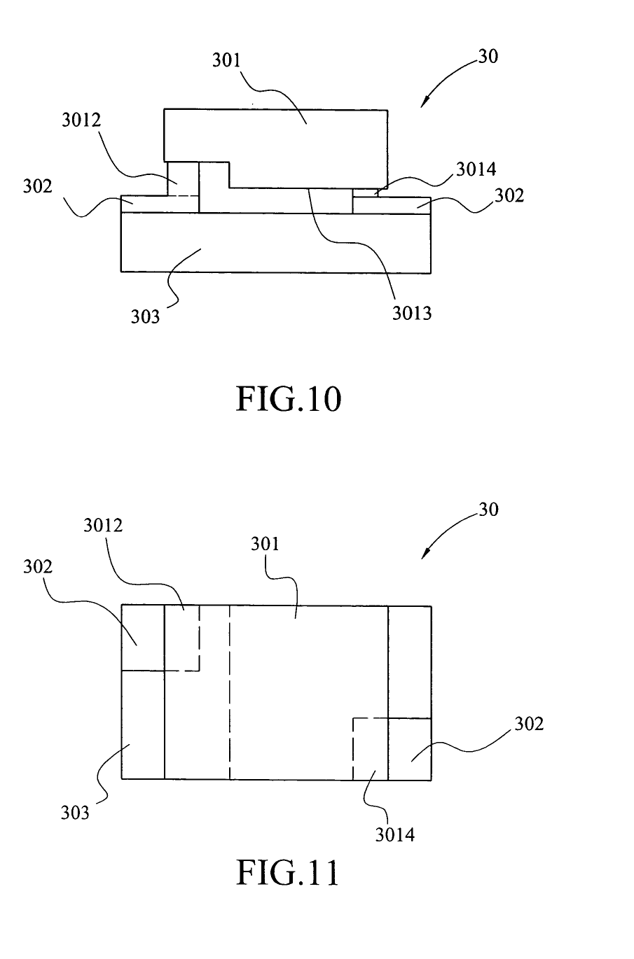

As shown in FIG. 9, after cutting along the cutting line 3031 the heat-dissipating substrate 303 is divided into several finished light-emitting chips 30 (see FIG. 10).

In FIG. 10, we show the light-emitting chip 30 formed using the disclosed fabrication method for light-emitting diodes. The chip 30 thus prepared has a light-emitting layer formed from an epitaxial chip 301, a set of metal electrodes 302 (including a p-electrode and an n-electrode), and a heat-dissipating substrate 303. The material of the epitaxial chip 301 is mainly GaN or it can be a group-II, III or IV epitaxial chip containing As, GaP, GaAsP, AlGaAs, or AlGaInP. The selection of materials depends upon the desired color of the light to be produced. For example, we can produce light-emitting layers that can produce red, green or ultraviolet light. The metal electrodes 302 are formed between the epitaxial chip 301 and the heat-dissipating substrate 303. Its upper surface is exposed above the epitaxial chip 301 to form a metal wire connection part 3021 for the convenience of future bonding processes during packaging. The bottom of the metal electrodes is in contact with the heat-dissipating substrate 302. Therefore, one can use the good heat dissipation character of the heat-dissipating substrate 302 to be the heat-dissipating structure of the light-emitting chip. In the applications, the temperature of epitaxial chip and the metal electrodes during the work can be dissipated via the heat-dissipating substrate 302. The finished light-emitting chip 30 can emit light by imposing an appropriate voltage on the two metal electrodes. The color of the produced light varies according to the material of the epitaxial chip 301. For example, the GaN light-emitting layer can produce blue light.

From the above description, we know that the light-emitting chip 30 manufactured according to the disclosed method has the following basic structure and functioning principles. Once a voltage is imposed on the two metal electrodes 302, the electric energy is converted into optical energy for the light-emitting layer formed from the epitaxial chip 301 to be a light source. We use insulating and heat-dissipating materials as the substrate of the light-emitting layer (i.e. the heat-dissipating substrate 303). When the voltage imposed on the two metal electrodes 302 makes the light-emitting layer of the epitaxial chip 301 light up, the work temperature of the light-emitting layer starts to rise. In many applications, the electronic devices require a high-power light source. However, how-power operations imply an increasing work temperature. If the temperature cannot be effectively reduced, the light-emitting efficiency may be attenuated (light attenuation).

The invention uses the insulating and fast heat-dissipating characters of the heat-dissipating substrate 303 to transfer the heat produced by the light-emitting chip via the metal electrodes 302 to the heat-dissipating substrate 303. This achieves the effects of rapid heat dissipation and of raising the power of the light-emitting chip 30. Materials that are suitable for the heat-dissipating substrate include ceramics, aluminum oxides, aluminum nitrides, or their mixtures.

Please refer to FIG. 11. From the top view of the light-emitting chip 30, one sees that the upper surface of the light-emitting layer formed from the epitaxial chip 301 is different from conventional ones. Due to the design of the locations of the metal electrodes 302, the upper surface of the light-emitting layer 301 is not shielded. That is, when the light-emitting layer 301 produces light the whole upper surface emits light, effectively increasing the light-emitting efficiency of the system. Furthermore, when the light-emitting chip 30 is use din a light-emitting diode, the metal electrodes 302 are exposed outside the epitaxial chip 301. Thus, the bonding machine does not bombard the epitaxial chip 301 while bonding, protecting the epitaxial chip 301 from damages.

In conclusion, the disclosed method forms several grooves on a surface and attaches several metal blocks of epitaxial chips. Moreover, a heat-dissipating substrate with several metal electrodes is bonded to the corresponding position. Cutting is performed after the bonding is completed, leaving several independent light-emitting chips.

The above-mentioned epitaxial chips and heat-dissipating substrate can be manufactured at different locations and shipped to a same location for bonding. Afterwards, they are cut into individual light-emitting chips. With the disclosed, one is then able to produce light-emitting chips with a heat-dissipating structure for effectively releasing their heat during operations.

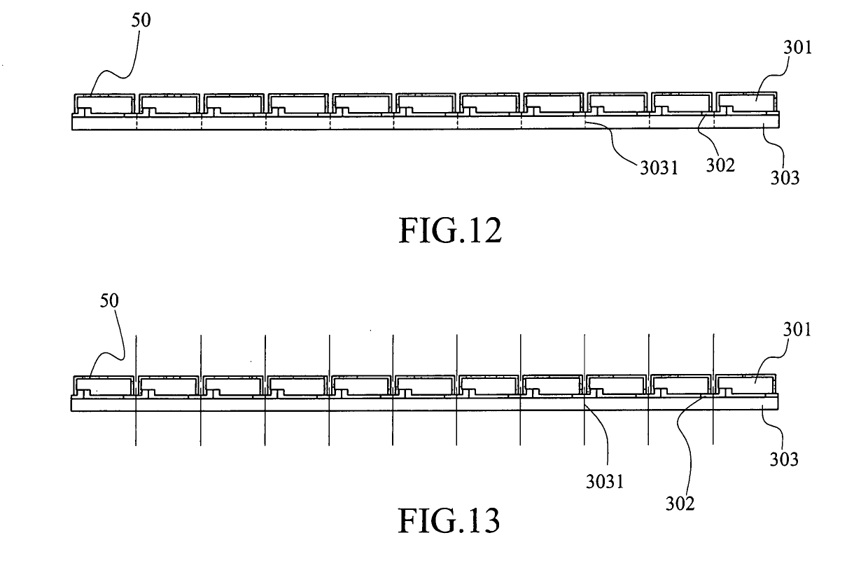

FIG. 12 shows an embodiment of the invention. To enlarge the application range of the disclosed light-emitting chips, one can incorporate other methods into the disclosed manufacturing process so that other colors (such as white) of light are emitted by the produced light-emitting chip. The current embodiment includes a step of coating a color mixture layer 50 on the epitaxial chip before step 404 of the original procedure, so that the surface of the epitaxial chip 301 is covered by the color mixture layer 50. Once the coating is finished, we start the cutting step (as in FIG. 13). In this way, each of the light-emitting chips 30 produced after cutting has a color mixture layer 50 covering the surface of the epitaxial chip 301. The effect gained from this additional step is to let the light emitted from the epitaxial chip 301 shine on the color mixture layer 50 to excite the materials therein to emit light of different wavelengths. Such beams of light are mixed inside the color mixture layer 50 and then scattered out. Therefore, we obtain a beam with a mixture of different wavelengths of light. Such a color mixture layer 50 is formed from mixed scattering particles, fluorescent particles, and diffracting particles. The scattering particles are quartz, glass or other transparent polymers. The diffracting particles are TiBaO, TiO, silicon oxides, or their combinations. The fluorescent particles are inorganic fluorescent materials. Moreover, the step of coating the color mixture layer 50 can be performed before step 401. That is, the coating is performed after the epitaxial chip is finished.

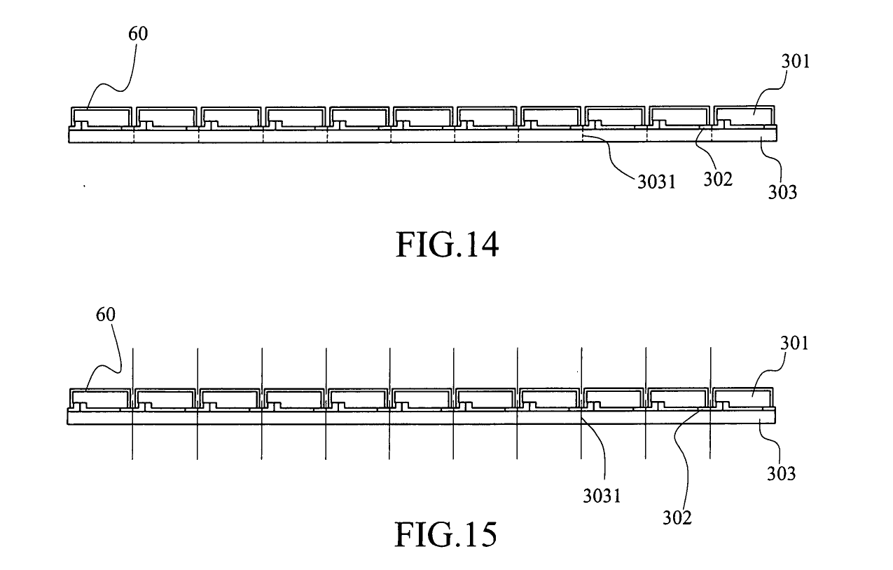

FIG. 14 shows another embodiment of the invention. In this embodiment, the epitaxial chip 301 is coated with a fluorescent layer 60 before step 404. The cutting step is performed after the coating is done (as in FIG. 15). Thus, the surface of the epitaxial chip 301 in each of the light-emitting chips 30 is covered with a fluorescent layer 60. Its effect is to let the light generated by the light-emitting layer 301 shine on the fluorescent layer 60, exciting the fluorescent material to emit light of another wavelength. With the covering of the coating layer, the light from the light-emitting layer 301 is mixed with the excited light before they come out. Therefore, the manufacturers can select an appropriate inorganic fluorescent material to generate different colors of light according to their needs. For example, one can use silicon nitride as the light-emitting layer along with yttrium aluminum garnet (YAG) powders to generate white light.

In summary, the disclosed fabrication method for light-emitting chips can achieve the following effects:
(1) The produced light-emitting chip has a heat-dissipating structure with good heat dissipation effects.
(2) One can simultaneously produce several light-emitting chips by cutting without repeating the process for individual chips. This greatly facilitates the production processes and increases the yield.
(3) The light-emitting chip thus made has the metal electrodes sandwiched between the epitaxial chip and the heat-dissipating substrate. Therefore, the main light-emitting area is not sacrificed and the light-emitting efficiency is higher.
(4) The light-emitting chip has a heat-dissipating substrate to release its heat. Thus, the chip can have a higher power for wider applications.
(5) The metal electrodes extrude from the epitaxial chip. The chip thus will not be hurt by the bonding machine during bonding, ensuring the yield.

To sum up, the invention indeed can produce light-emitting chips with good heat dissipation effects to provide a higher power output. At the same time, the disclosed fabrication method can produce light-emitting chips that can make whole-area light emissions, increasing the efficiency.

Certain variations would be apparent to those skilled in the art, which variations are considered within the spirit and scope of the claimed invention.

1. A fabrication method for light-emitting chips to produce a plurality of light-emitting chips with fast heat-dissipating characters after cutting, the method comprising the steps of:
providing an epitaxial chip and a heat-dissipating substrate, the epitaxial chip having a surface which is attached with a plurality of metal blocks and formed with a plurality of grooves, the heat-dissipating substrate being attached with a plurality of metal electrodes;
bonding the metal blocks of the epitaxial chips and the metal electrodes of the heat-dissipating electrodes after aligning them; and
cutting the bonded epitaxial chip and the heat-dissipating substrate to form a plurality of independent light-emitting chips.

2. The fabrication method of claim 1, wherein the metal blocks attached on the epitaxial chip is made of a material selected from the group consisting of gold, silver, tin, and their alloys that have highly electric and thermal conductive properties.

3. The fabrication method of claim 1, wherein the metal blocks on the epitaxial chip is attached by a method selected from electroplating, evaporation and sputtering.

4. The fabrication method of claim 1, wherein the bonding between the metal electrodes on the heat-dissipating substrate and the metal blocks on the epitaxial chip is performed via a method selected from electro-soldering, welding, and supersonic bonding.

5. The fabrication method of claim 1, wherein the material of the heat-dissipating substrate is selected from the group consisting of ceramics, aluminum oxides, and aluminum nitrides.

6. The fabrication method of claim 1, wherein the grooves of the epitaxial chip are formed by laser machining or a lithography process.

7. A fabrication method for light-emitting chips with a color mixture layer for making a light-emitting chip that emits light with a mixture of at least two different wavelengths, the method comprising the steps of:
providing an epitaxial chip and a heat-dissipating substrate, the epitaxial chip having a surface which is attached with a plurality of metal blocks, formed with a plurality of grooves and coated with a color mixture layer, the heat-dissipating substrate being attached with a plurality of metal electrodes;
bonding the metal blocks of the epitaxial chips and the metal electrodes of the heat-dissipating electrodes after aligning them; and
cutting the bonded epitaxial chip and the heat-dissipating substrate to form a plurality of independent light-emitting chips.

8. The fabrication method of claim 7, wherein the plurality of metal blocks attached on the epitaxial chip is made of a material selected from the group consisting of gold, silver, tin, and their alloys that have highly electric and thermal conductive properties.

9. The fabrication method of claim 7, wherein the plurality of metal blocks on the epitaxial chip is attached by a method selected from electroplating, evaporation and sputtering.

10. The fabrication method of claim 7, wherein the bonding between the metal electrodes on the heat-dissipating substrate and the metal blocks on the epitaxial chip is performed via a method selected from electro-soldering, welding, and supersonic bonding.

11. The fabrication method of claim 7, wherein the material of the heat-dissipating substrate is selected from the group consisting of ceramics, aluminum oxides, and aluminum nitrides.

12. The fabrication method of claim 7, wherein the color mixture layer is formed from mixed scattering particles, fluorescent particles, and diffracting particles.

13. The fabrication method of claim 7, wherein the grooves of the epitaxial chip are formed by laser machining or a lithography process.

14. A fabrication method for light-emitting chips with a fluorescent layer for making a light-emitting chip that emits light with a mixture of at least two different wavelengths, the method comprising the steps of:
providing an epitaxial chip and a heat-dissipating substrate, the epitaxial chip having a surface which is attached with a plurality of metal blocks, formed with a plurality of grooves and coated with a fluorescent layer, the heat-dissipating substrate being attached with a plurality of metal electrodes;
bonding the metal blocks of the epitaxial chips and the metal electrodes of the heat-dissipating electrodes after aligning them; and
cutting the bonded epitaxial chip and the heat-dissipating substrate to form a plurality of independent light-emitting chips.

15. The fabrication method of claim 14, wherein the plurality of metal blocks attached on the epitaxial chip is made of a material selected from the group consisting of gold, silver, tin, and their alloys that have highly electric and thermal conductive properties.

16. The fabrication method of claim 14, wherein the plurality of metal blocks on the epitaxial chip is attached by a method selected from electroplating, evaporation and sputtering.

17. The fabrication method of claim 14, wherein the bonding between the metal electrodes on the heat-dissipating substrate and the metal blocks on the epitaxial chip is performed via a method selected from electro-soldering, welding, and supersonic bonding.

18. The fabrication method of claim 14, wherein the material of the heat-dissipating substrate is selected from the group consisting of ceramics, aluminum oxides, and aluminum nitrides.

19. The fabrication method of claim 14, wherein the fluorescent layer contains yttrium aluminum garnet (YAG) powders.

20. The fabrication method of claim 14, wherein the grooves of the epitaxial chip are formed by laser machining or a lithography process.
